(19) United States
(12) Patent Application Publication
(10) Pub. No.: US 2025/0271469 A1
(43) Pub. Date: Aug. 28, 2025

(54) CURRENT SENSOR AND SEMICONDUCTOR-TYPE CURRENT SENSOR

(71) Applicant: TDK Corporation, Tokyo (JP)

(72) Inventors: Takehiro ISODA, Tokyo (JP); Hiraku HIRABAYSHI, Tokyo (JP)

(73) Assignee: TDK Corporation, Tokyo (JP)

(21) Appl. No.: 18/959,742

(22) Filed: Nov. 26, 2024

(30) Foreign Application Priority Data
Feb. 22, 2024 (JP) 2024-025401

(51) Int. Cl. G01R 15/20; G01R 33/09

(52) U.S. Cl. CPC G01R 15/205; G01R 33/093

(57) ABSTRACT

A current sensor includes: a bus bar; magnetoresistive effect elements (MR elements) that are disposed in pairs over a corresponding one of bent portions of the bus bar that are symmetrical; and an application portion that applies a bias magnetic field to each MR element, and when the MR elements form a bridge circuit, magnetization directions of fixed layers of the two MR elements are perpendicular to the center line of the bus bar and opposite to each other, and magnetization directions of the fixed layers are perpendicular to the center line and opposite to each other, and in a state in which the bus bar is not energized and the bias magnetic field is applied, magnetization directions of the free layers are parallel to the center line and in the same direction, and magnetization directions of the free layers of the other two MR elements are opposite.

### CROSS-REFERENCE TO RELATED APPLICATION

The present application is based upon and claims the benefit of priority from Japanese Patent Application No. 2024-025401, filed on Feb. 22, 2024, the entire contents of which are hereby incorporated by reference.

### BACKGROUND

The present disclosure relates to a current sensor and a semiconductor-type current sensor.

To detect a current flowing in a current passage that is to be detected, a current sensor is known that is interposed in the current passage to detect the current value of the current. The current sensor may include a current passage, which may be bent in a U-shape, for example, and detects an induced magnetic field generated by the current flowing through the current passage by using a magnetoresistive effect element (see, for example, Japanese Patent No. 5853316).

### SUMMARY

A current sensor according to a first aspect of the present disclosure includes: a bus bar including a first straight portion and a second straight portion that are on opposite sides across a center line therebetween and parallel to each other, and including a first bent portion and a second bent portion that are continuous with one end of the first straight portion and one end of the second straight portion, respectively, and are symmetrical to each other with respect to the center line; a first detection element, a second detection element, a third detection element, and a fourth detection element, each of which is a magnetoresistive effect element including a fixed layer and a free layer, the first element and the second element being disposed over the first bent portion, and the third detection element and the fourth detection element being disposed over the second bent portion; and an application portion configured to apply a bias magnetic field to the free layer of each of the first to fourth detection elements, in which when the first to fourth detection elements form a bridge circuit, magnetization directions of the fixed layers of the first detection element and the second detection element are directions perpendicular to the center line and opposite to each other, and magnetization directions of the fixed layers of the third detection element and the fourth detection element are directions perpendicular to the center line and opposite to each other, and in a state in which the bus bar is not energized and the bias magnetic field is applied by the application portion, magnetization directions of the free layers of two detection elements forming a first set among the first to fourth detection elements are parallel to the center line and in a same direction as each other, and magnetization directions of the free layers of the other two detection elements forming a second set are parallel to the center line, in a same direction as each other, and opposite to the magnetization directions of the two detection elements forming the first set.

A semiconductor-type current sensor according to a second aspect of the present disclosure includes the above-described current sensor accommodated in a single semiconductor package.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is an exploded perspective view of a current sensor according to example embodiment;

FIG. 2 is a diagram illustrating an induced magnetic field generated in a bus bar and an arrangement of detection elements;

FIG. 3 is a diagram showing the relationship between the configuration of a bridge circuit and two semiconductor chips;

FIG. 4A is a diagram showing the arrangement of a pair of a first chip and a second chip relative to a first bent portion and a second bent portion;

FIG. 4B is a diagram showing the relationship between the current applied to a bus bar 110 and linearity errors;

FIG. 5 is a diagram illustrating the interrelationship between two semiconductor chips;

FIG. 6 is a diagram illustrating variations of the combination of detection elements;

FIG. 7 is a diagram showing another relationship between the configuration of a full-bridge circuit and two semiconductor chips;

FIG. 8 is a diagram illustrating another interrelationship between two semiconductor chips;

FIG. 9 is a diagram illustrating variations of the combination of detection elements; and

FIG. 10 is a diagram showing the configuration of a semiconductor-type current sensor according to another embodiment.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

Conventional current sensors have a problem where the linearity of the detected resistance value, which is an output value with respect to the value of a current flowing through the current passage as an input value, may degrade due to the properties of the magnetoresistive elements and the arrangement of the magnetoresistive elements relative to the current passage.

The present disclosure has been made to solve such a problem, and provides a current sensor or the like that has good linearity of output values with respect to input values.

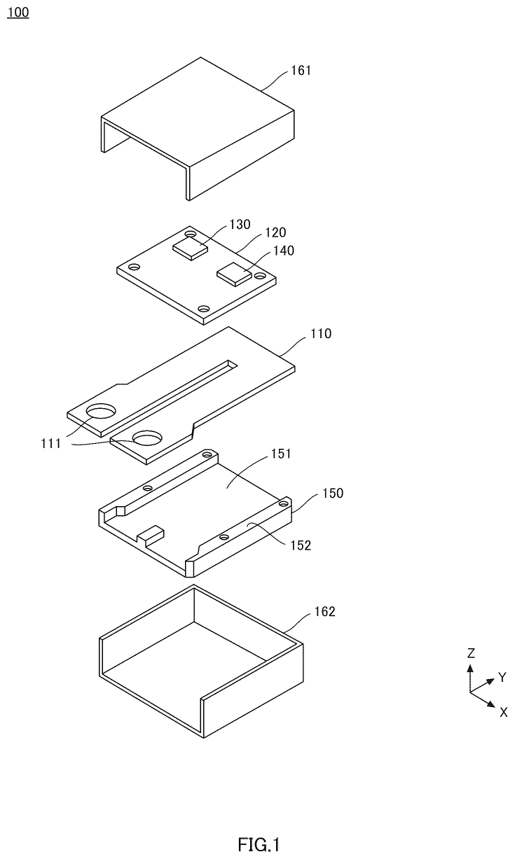

FIG. 1 is an exploded perspective view of a current sensor 100 according to the present embodiment. The current sensor 100 according to this embodiment includes a bus bar 110, a substrate 120, a first chip 130, a second chip 140, a support plate 150, a first shield case 161, and a second shield case 162. The bus bar 110 is a current passage and is made of a good conductor such as copper (Cu). The bus bar 110, the specific shape of which will be described below, is a flat plate that is substantially U-shaped as a whole, and has two end portions each including a connection hole 111 for connecting a conductor as a current passage to be measured.

On the substrate 120, the first chip 130 and the second chip 140, which are semiconductor chips each including two magnetoresistive effect elements, are mounted. The first and second chips 130 and 140 may be mounted on the substrate 120 as a magnetic sensor package packaged with synthetic resin. The substrate 120 has input/output terminals (not illustrated) and receives power from an external power source and outputs an output signal of a bridge circuit formed by combining the magnetoresistive effect elements of the first and second chips 130 and 140.

The support plate 150 is a plate-shaped member supporting the bus bar 110 and the substrate 120. An accommodation portion 151 is a recess provided in the center of the support plate 150 to match the shape of the bus bar 110, and side edge portions 152 are receivers for the substrate 120 provided on both sides of the support plate 150. When the accommodation portion 151 accommodates the bus bar 110 and the substrate 120 is fixed to the side edge portions 152, the first and second chips 130 and 140 are located at predetermined positions relative to the bus bar 110 as described below.

The first shield case 161 and the second shield case 162 sandwich the bus bar 110, the substrate 120, and the support plate 150, which are assembled together, and surround most of the bus bar 110 except for the protruding ends. The first and second shield cases 161 and 162 are formed using a synthetic resin such as ABS in which magnetic powder is dispersed. The first and second shield cases 161 and 162 prevent the intrusion of disturbance magnetic fields, allowing each magnetoresistive effect element to accurately detect an induced magnetic field that is generated when a current is applied to the bus bar 110.

In this embodiment, as indicated by the coordinate axes in the figure, the stacking direction of the substrate 120 relative to the bus bar 110 is defined as the Z-axis direction, and two axes perpendicular to the Z-axis direction are defined as the X-axis direction and the Y-axis direction. In the subsequent drawings, similar coordinate axes based on the state in which the current sensor 100 is disposed as in FIG. 1 are also included to indicate the orientation of elements depicted in each drawing.

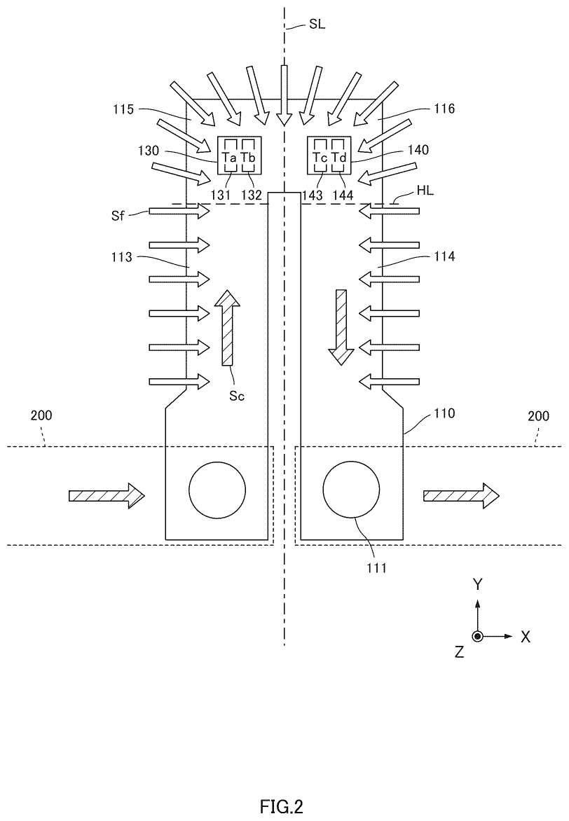

FIG. 2 is a diagram illustrating an induced magnetic field generated in the bus bar 110 and the arrangement of detection elements. Specifically, the figure illustrates the bus bar 110, the first chip 130, and the second chip 140 of the current sensor 100 as viewed from the Z-axis direction, with a conductor 200, which is the current passage to be detected, indicated by dotted lines.

The two end portions of the conductor 200, which are formed by dividing the conductor 200, are each coupled to the corresponding one of the two ends of the bus bar 110 through the connection hole 111, so that the conductor 200 is connected in series with the bus bar 110. A current to be measured Sc flows in the bus bar 110, which is connected in series with the conductor 200 in this manner, in the direction of the hatched arrows (or in the opposite direction). When a current to be measured Sc flows through the bus bar 110 in the direction of the hatched arrows, an induced magnetic field Sf is generated in the directions of the hollow arrows.

As described above, the bus bar 110 is a flat plate that is substantially U-shaped as a whole, and has a shape that is symmetrical with respect to the center line SL when observed from the Z-axis direction. More specifically, the bus bar 110 includes a first straight portion 113 and a second straight portion 114, which are on opposite sides of the center line SL and parallel to each other, and a first bent portion 115 and a second bent portion 116, which are continuous with one end of the first straight portion 113 and one end of the second straight portion 114, respectively (the ends opposite the open ends including the connection holes 111). The first and second bent portions 115 and 116 are symmetrical to each other with respect to the center line SL. The first and second straight portions 113 and 114 only need to allow a current to flow parallel to the center line, and may have a wide portion at each open end or a portion in which the thickness changes. The first and second bent portions 115 and 116 only need to cause the direction of the current to change continuously, and may each be bent in an L-shape as illustrated in the figure, or may be curved in a J-shape. In the figure, the boundary between the first straight portion 113 and the first bent portion 115, and the boundary between the second bent portion 116 and the second straight portion 114 are indicated by boundary lines HL, but these boundaries do not have to have a shape that is externally visible and may be regarded as positions at which the direction of the induced magnetic field Sf essentially begins to change. Furthermore, a current passage of a linear shape or another shape may be interposed between the first and second bent portions 115 and 116.

The direction of the induced magnetic field Sf changes depending on the position of the current flowing through the bus bar 110. In particular, in the first and second bent portions 115 and 116, as illustrated in the figure, the direction changes continuously over 180° from the positive X-axis direction, the negative Y-axis direction, and then to the negative X-axis direction. In this embodiment, when observed from the Z-axis direction, the first chip 130 is disposed so as to overlap the first bent portion 115, and the second chip 140 is disposed so as to overlap the second bent portion 116. That is, the mounting positions of the first and second chips 130 and 140 relative to the substrate 120 and the fixing position of the substrate 120 relative to the support plate 150 are adjusted so that the first and second chips 130 and 140 are arranged in this manner. Since the first and second chips 130 and 140 are formed on a single substrate 120, the relative positions of these chips and the bus bar 110 can be easily adjusted.

The first chip 130 includes two magnetoresistive effect elements (a first detection element 131 and a second detection element 132). Likewise, the second chip 140 includes two magnetoresistive effect elements (a third detection element 143 and a fourth detection element 144).

The magnetoresistive elements used in this embodiment are spin-valve type MR elements. The MR element has a configuration in which an antiferromagnetic layer extending in the XY direction, a magnetization fixed layer, which has magnetization with a fixed direction, a gap layer, and a free layer, which has magnetization with a direction that changes depending on the direction of the target magnetic field, are stacked in this order in the positive Z-axis direction. The antiferromagnetic layer is made of an antiferromagnetic material and establishes exchange coupling with the magnetization fixed layer to fix the direction of magnetization of the magnetization fixed layer. The magnetization fixed layer may be what is known as a self-pinned type fixed layer (synthetic ferri pinned layer (SFP layer)). The self-pinned type fixed layer has a laminated ferrimagnetic structure in which a ferromagnetic layer, a non-magnetic intermediate layer, and a ferromagnetic layer are stacked, and the two ferromagnetic layers are antiferromagnetically coupled. When the magnetization fixed layer is a self-pinned type fixed layer, the antiferromagnetic layer may be omitted.

The free layer generally has shape anisotropy in which the direction of easy magnetization is perpendicular to the direction of magnetization of the magnetization fixed layer. In the MR element of the present embodiment, the free layer has a shape elongated in the Y-axis direction. In the MR element configured in this manner, the resistance value changes depending on the angle formed between the magnetization direction of the free layer and the magnetization direction of the magnetization fixed layer. When this angle is 0°, the resistance value is at its minimum, and when it is 180°, the resistance value is at its maximum. The stacking direction of the layers in the MR element may be reversed to that described above. The MR element may be a tunnel magnetoresistive (TMR) element or a giant magnetoresistive (GMR) element. In a TMR element, the gap layer is a tunnel barrier layer. In a GMR element, the gap layer is a non-magnetic conductive layer.

When the first chip 130 is disposed over the first bent portion 115, the first detection element 131 is located at a first arrangement Ta, and the second detection element 132 is located at a second arrangement Tb. Likewise, when the second chip 140 is disposed over the second bent portion 116, the third detection element 143 is located at a third arrangement Tc, and the fourth detection element 144 is located at a fourth arrangement Td. Here, to clarify the relationship between each of the two detection elements and the bridge circuit, which will be described below, the first arrangement Ta and the second arrangement Tb, and the third arrangement Tc and the fourth arrangement Td, which are adjacent along the X-axis direction, are adopted for convenience. However, the arrangement of two detection elements may be adjacent along the Y-axis direction or along another direction. Nevertheless, the arrangement of the first and second detection elements 131 and 132 is suitably symmetrical to the arrangement of the third and fourth detection elements 143 and 144 with respect to the center line SL.

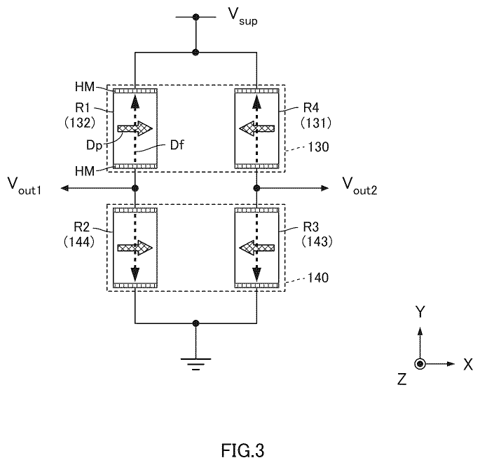

FIG. 3 is a diagram showing the relationship between the configuration of a full-bridge circuit formed by four detection elements and two semiconductor chips. In the figure, each of a first resistor R1, a second resistor R2, a third resistor R3, and a fourth resistor R4 is a magnetoresistive effect element according to the present embodiment. Here, the first resistor R1 is the second detection element 132 included in the first chip 130, the second resistor R2 is the fourth detection element 144 included in the second chip 140, the third resistor R3 is the third detection element 143 included in the second chip 140, and the fourth resistor R4 is the first detection element 131 included in the first chip 130.

In the figure, PIN directions Dp indicated by crosshatched arrows represent the magnetization directions of the fixed layers, and FREE directions Df indicated by dotted arrows represent the magnetization directions of the free layers in a state in which a bias magnetic field is applied by a hard bias layer HM. The hard bias layer (hard magnet) is formed in each magnetoresistive effect element, and the magnetization direction of the free layer can be determined for each magnetoresistive effect element. In the following figures, for simplicity, the hard bias layer HM is omitted in each element unless otherwise specified.

The first resistor R1 (second detection element 132) and the second resistor R2 (fourth detection element 144) are connected in series with each other between a DC power supply and ground to form a half-bridge circuit (second half-bridge circuit), and output a first output voltage Vₒᵤₜ₁, which corresponds to the strength of the magnetism applied to each of the first resistor R1 and the second resistor R2, at the midpoint between the first and second resistors R1 and R2. The fourth resistor R4 (first detection element 131) and the third resistor R3 (third detection element 143) are similarly connected in series with each other between the DC power supply and ground to form a half-bridge circuit (first half-bridge circuit), and output a second output voltage Vₒᵤₜ₂, which corresponds to the strength of the magnetism applied to each of the fourth resistor R4 and the third resistor R3, at the midpoint between the fourth resistor R4 and the third resistor R3. The DC power supply supplies a constant supply voltage V_{SUP}, and the first to fourth resistors R1 to R4 form a full-bridge circuit as a whole.

When the first chip 130 is disposed so as to overlap the first bent portion 115, the PIN direction Dp of the first resistor R1 agrees with the positive X-axis direction perpendicular to the center line SL. At this time, the FREE direction Df of the first resistor R1 agrees with the positive Y-axis direction parallel to the center line SL. When a current to be measured Sc flows through the first bent portion 115, the induced magnetic field Sf thus generated has a component in the positive X-axis direction (see FIG. 2), so that the resistance value of the first resistor R1 decreases in accordance with the strength of the induced magnetic field Sf. When the second chip 140 is disposed so as to overlap the second bent portion 116, the PIN direction Dp of the second resistor R2 agrees with the positive X-axis direction perpendicular to the center line SL. At this time, the FREE direction Df of the second resistor R2 agrees with the negative Y-axis direction parallel to the center line SL. When the current to be measured Sc flows through the second bent portion 116, the induced magnetic field Sf thus generated has a component in the negative X-axis direction (see FIG. 2), so that the resistance value of the second resistor R2 increases in accordance with the strength of the induced magnetic field Sf. The first output voltage Vₒᵤₜ₁ is an output obtained by dividing the supply voltage V_{SUP} by the resistance value of the first resistor R1 and the resistance value of the second resistor R2, which change as described above.

When the first chip 130 is disposed so as to overlap the first bent portion 115, the PIN direction Dp of the fourth resistor R4 agrees with the negative X-axis direction perpendicular to the center line SL. At this time, the FREE direction Df of the fourth resistor R4 agrees with the positive Y-axis direction parallel to the center line SL. When the current to be measured Sc flows through the first bent portion 115, the induced magnetic field Sf thus generated has a component in the positive X-axis direction (see FIG. 2), so that the resistance value of the fourth resistor R4 increases in accordance with the strength of the induced magnetic field Sf. When the second chip 140 is disposed so as to overlap the second bent portion 116, the PIN direction Dp of the third resistor R3 agrees with the negative X-axis direction perpendicular to the center line SL. At this time, the FREE direction Df of the third resistor R3 agrees with the negative Y-axis direction parallel to the center line SL. When the current to be measured Sc flows through the second bent portion 116, the induced magnetic field Sf thus generated has a component in the negative X-axis direction (see FIG. 2), so that the resistance value of the third resistor R3 decreases in accordance with the strength of the induced magnetic field Sf. The second output voltage Vₒᵤₜ₂ is an output obtained by dividing the supply voltage V_{SUP} by the resistance value of the fourth resistor R4 and the resistance value of the third resistor R3, which change as described above.

Accordingly, when a larger current to be measured Sc flows through the first and second bent portions 115 and 116, the first output voltage Vₒᵤₜ₁ becomes larger and the second output voltage Vₒᵤₜ₂ becomes smaller. In other words, since the first output voltage Vₒᵤₜ₁ and the second output voltage Vₒᵤₜ₂ vary complementarily depending on the magnitude of the current to be measured Sc, the full-bridge circuit as a whole is suitable as a measurement circuit for accurately measuring the magnitude of the current to be measured Sc.

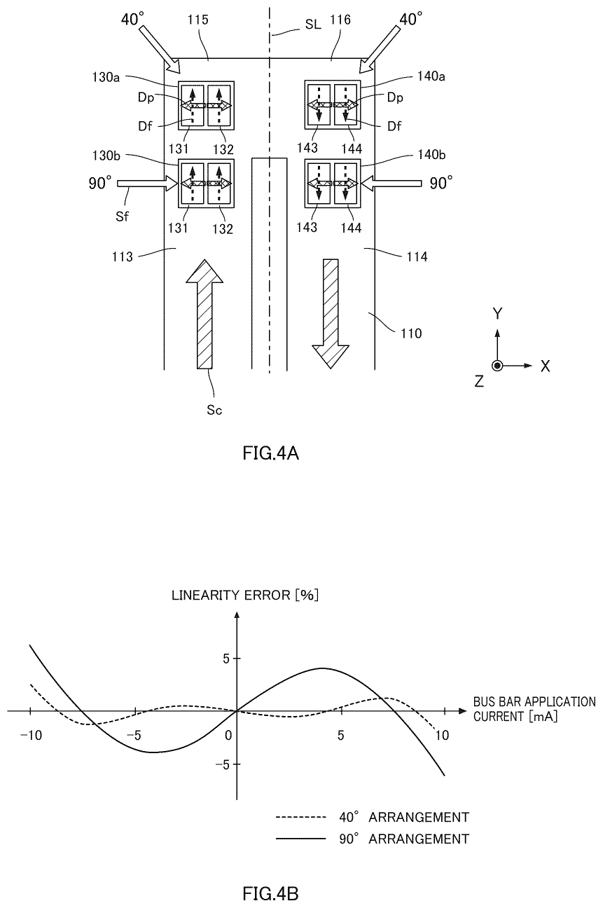

FIG. 4A is a diagram showing the arrangement of a pair of the first and second chips 130 and 140 relative to the first and second bent portions 115 and 116, and FIG. 4B is a diagram showing the relationship between the current applied to the bus bar 110 and the linearity error in the arrangement of FIG. 4A.

In FIG. 4A, the first chip 130a illustrates a state in which the first chip 130 is disposed at a position over the first bent portion 115 at which the angle formed between the direction of the induced magnetic field Sf and the center line SL is 40°. The second chip 140a is arranged paired with the first chip 130a and illustrates a state in which the second chip 140 is disposed at a position over the second bent portion 116 at which the angle formed between the direction of the induced magnetic field Sf and the center line SL is 40°. As described with reference to FIG. 2, the first chip 130a includes the first and second detection elements 131 and 132, and the second chip 140a includes the third and fourth detection elements 143 and 144. The arrangement position of the first chip 130a may be based on the midpoint between the first and second detection elements 131 and 132, and the arrangement position of the second chip 140a may be based on the midpoint between the third and fourth detection elements 143 and 144. As described with reference to FIG. 3, the PIN direction Dp and the FREE direction Df of each detection element are directed as illustrated in the figure.

Also, in FIG. 4A, the first chip 130b illustrates a state in which the first chip 130 is disposed at a position near the boundary between the first bent portion 115 and the first straight portion 113 at which the angle formed between the direction of the induced magnetic field Sf and the center line SL is 90°. The second chip 140b is arranged paired with the first chip 130b and illustrates a state in which the second chip 140 is disposed at a position near the boundary between the second bent portion 116 and the second straight portion 114 at which the angle formed between the direction of the induced magnetic field Sf and the center line SL is 90°. In a similar manner as the first and second chips 130a and 140a, the arrangement position of the first chip 130b may be based on the midpoint between the first and second detection elements 131 and 132, and the arrangement position of the second chip 140b may be based on the midpoint between the third and fourth detection elements 143 and 144. The PIN direction Dp and the FREE direction Df of each detection element are directed as illustrated in the figure.

In FIG. 4B, the horizontal axis represents the current value (mA) of the current to be measured Sc flowing through the bus bar 110, and the vertical axis represents the linearity error (%). The linearity error indicates, in percentage, the degree to which the output signal (the difference signal between the first output voltage Vout and the second output voltage Vₒᵤₜ₂ described with reference to FIG. 3) that should be output in proportion to the current to be measured Sc that is actually applied deviates from an ideal straight line.

The dotted line indicates the simulation result of the pair of the first and second chips 130a and 140a disposed at positions at which the angle formed between the direction of the induced magnetic field Sf and the center line SL is 40°, and the solid line indicates the simulation result of the pair of the first and second chips 130b and 140b disposed at positions at which the angle formed between the direction of the induced magnetic field Sf and the center line SL is 90°. As is clear from the figure, it is understood that the dotted line generally has a smaller linearity error than the solid line with respect to the change in the current to be measured Sc. The inventors conducted repeated simulations and found that the linearity error can be kept small with respect to the change in the current to be measured Sc in general when the first and second detection elements 131 and 132 over the first bent portion 115, and the third and fourth detection elements 143 and 144 over the second bent portion 116 are disposed at positions at which the angle formed between the center line SL and the direction of the induced magnetic field Sf generated when the current to be measured Sc is applied to the bus bar 110 is less than 90°. In particular, it has been found that linearity error can be kept small in a favorable manner when the formed angle is 25° or more and less than 90°, and furthermore, 30° or more and less than 60°.

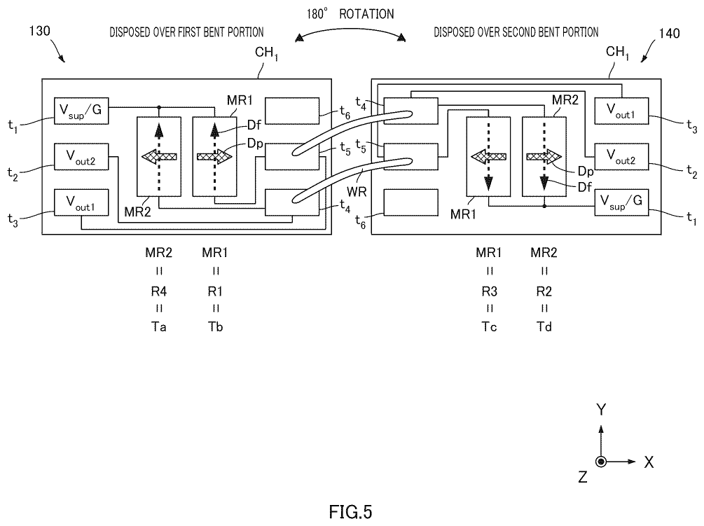

The relationship between the arrangement of the first and second detection elements 131 and 132 on the first chip 130 and the arrangement of the third and fourth detection elements 143 and 144 on the second chip 140 is now described. FIG. 5 is a diagram illustrating the interrelationship between two semiconductor chips (the first chip 130 and the second chip 140). In particular, the first chip 130 disposed over the first bent portion 115 is illustrated on the left side, and the second chip 140 disposed over the second bent portion 116 is illustrated on the right side.

The first chip 130 illustrated on the left includes a detection element MR1, which is a magnetoresistive effect element located on the right side in the central portion of the chip, and a similar detection element MR2 located on the left side in the central portion, and also includes terminals t₁ to t₆, which are wired or not wired to these detection elements as illustrated in the figure. When the first chip 130 is disposed over the first bent portion 115, the detection element MR2 located on the left side corresponds to the first arrangement Ta, and the detection element MR1 located on the right side corresponds to the second arrangement Tb (see FIG. 2). The terminal t₁ functions as a power supply terminal for supplying the supply voltage V_{SUP}, the terminal t₂ functions as an output terminal for outputting the second output voltage Vₒᵤₜ₂, the terminal t₃ functions as an output terminal for outputting the first output voltage Vout, and the terminals t₄ to t₆ can be used as connection pads.

The detection element MR1 includes a fixed layer whose PIN direction Dp agrees with the positive X-axis direction when disposed over the first bent portion 115, and also a free layer whose FREE direction Df agrees with the positive Y-axis direction when a bias magnetic field is applied. The detection element MR1 having such a fixed layer and a free layer corresponds to the first resistor R1 in the full-bridge circuit (see FIG. 3). Also, the detection element MR2 includes a fixed layer whose PIN direction Dp agrees with the negative X-axis direction when disposed over the first bent portion 115, and also a free layer whose FREE direction Df agrees with the positive Y-axis direction when a bias magnetic field is applied. The detection element MR2 having such a fixed layer and a free layer corresponds to the fourth resistor R4 in the full-bridge circuit (see FIG. 3).

In this embodiment, when a semiconductor chip CH₁ identical to this first chip 130 is rotated 180° around the Z axis, it can be used as the second chip 140 disposed over the second bent portion 116. In other words, semiconductor chips CH₁ having the same structure can be used as both the first chip 130 and the second chip 140.

Specifically, when the semiconductor chip CH₁ is rotated 180° around the Z axis, it functions as the second chip 140 illustrated on the right, in which the detection element MR1 is located on the left side in the central portion and the detection element MR2 is located on the right side in the central portion. When this second chip 140 is disposed over the second bent portion 116, the detection element MR1 located on the left side corresponds to the third arrangement Tc, and the detection element MR2 located on the right side corresponds to the fourth arrangement Td (see FIG. 2). Here, the terminal t₅ of the first chip 130 and the terminal t₄ of the second chip 140 are connected by a connection wire WR, and similarly, the terminal t₄ of the first chip 130 and the terminal t₅ of the second chip 140 are connected by a connection wire WR. When connected in this manner, the terminal t₁ of the second chip 140 functions as a ground terminal, the terminal t₂ functions as an output terminal for outputting the second output voltage Vₒᵤₜ₂, and the terminal t₃ functions as an output terminal for outputting the first output voltage Vₒᵤₜ₁. Either the terminal t₃ of the first chip 130 or the terminal t₃ of the second chip 140 may be used as the output terminal for outputting the first output voltage Vₒᵤₜ₁. Likewise, either the terminal t₂ of the first chip 130 or the terminal t₂ of the second chip 140 may be used as the output terminal for outputting the second output voltage Vₒᵤₜ₂.

The detection element MR1 has a fixed layer whose PIN direction Dp agrees with the negative X-axis direction when disposed over the second bent portion 116, and also a free layer whose FREE direction Df agrees with the negative Y-axis direction when a bias magnetic field is applied. The detection element MR1 having such a fixed layer and a free layer corresponds to the third resistor R3 in the full-bridge circuit (see FIG. 3). Also, the detection element MR2 includes a fixed layer whose PIN direction Dp agrees with the positive X-axis direction when disposed over the second bent portion 116, and also a free layer whose FREE direction Df agrees with the negative Y-axis direction when a bias magnetic field is applied. The detection element MR2 having such a fixed layer and a free layer corresponds to the second resistor R2 in the full-bridge circuit (see FIG. 3). In this manner, semiconductor chips CH₁ having the same structure can be used as the first chip 130 disposed over the first bent portion 115 and the second chip 140 disposed over the second bent portion 116. This contributes to reducing the number of parts and manufacturing costs.

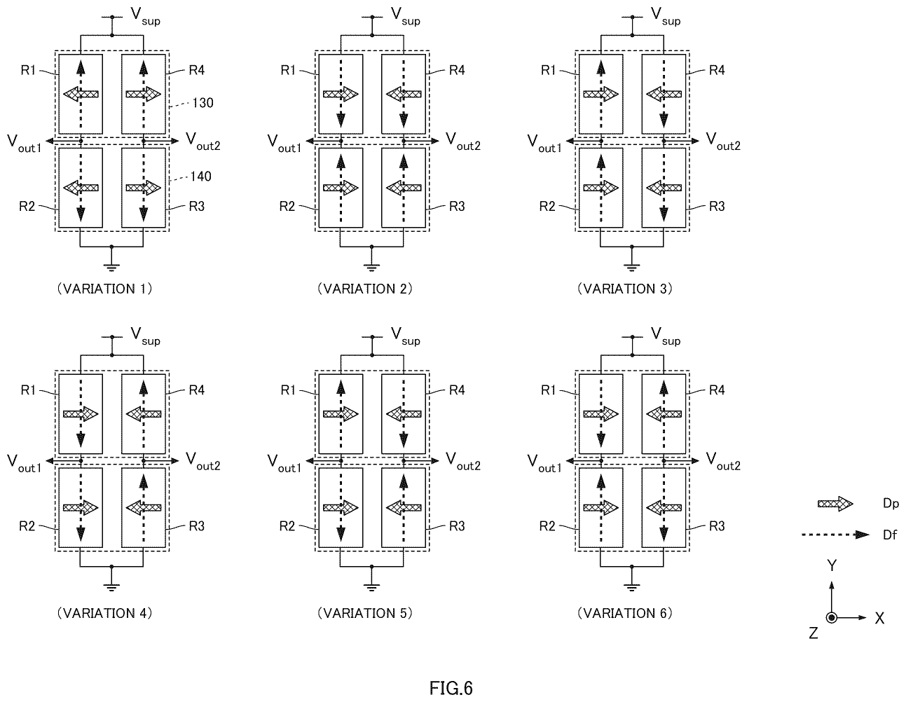

Variations of the combination of four detection elements that can favorably limit linearity errors as illustrated in FIGS. 4A and 4B are now described. FIG. 6 is a diagram for describing variations of the combination of detection elements.

With the present embodiment, there are various variations of the combination of detection elements that can favorably limit linearity errors. In the example described using FIG. 3, the PIN direction Dp of the first resistor R1 (second detection element 132) included in the first chip 130 is the positive X-axis direction, and the FREE direction Df when a bias magnetic field is applied is the positive Y-axis direction. Also, the PIN direction Dp of the second resistor R2 (fourth detection element 144) included in the second chip 140 is the positive X-axis direction, and the FREE direction Df when a bias magnetic field is applied is the negative Y-axis direction. Furthermore, the PIN direction Dp of the third resistor R3 (third detection element 143) included in the second chip 140 is the negative X-axis direction, and the FREE direction Df when a bias magnetic field is applied is the negative Y-axis direction. The PIN direction Dp of the fourth resistor R4 (first detection element 131) included in the first chip 130 is the negative X-axis direction, and the FREE direction Df when a bias magnetic field is applied is the positive Y-axis direction.

The inventors conducted repeated simulations and found that, among the combinations of the PIN direction Dp and the FREE direction Df of the detection elements, the possible combinations that can be variations of the present embodiment satisfy the following condition (1) regarding the magnetization direction of the fixed layer (PIN direction Dp) and condition (2) regarding the magnetization direction of the free layer (FREE direction Df). That is, (1) the PIN directions Dp of the first detection element 131 (fourth resistor R4) and the second detection element 132 (first resistor R1) included in the first chip 130 are directions (X-axis directions) perpendicular to the center line SL of the bus bar 110 and opposite to each other, and the PIN directions Dp of the third detection element 143 (third resistor R3) and the fourth detection element 144 (second resistor R2) included in the second chip 140 are directions (X-axis directions) perpendicular to the center line SL of the bus bar 110 and opposite to each other, and (2) in a state in which the bus bar 110 is not energized and a bias magnetic field is applied, the FREE directions Df of the two detection elements forming the first set (the combination of the first and second detection elements 131 and 132 in the example of FIG. 3) among the first to fourth detection elements 131 to 144 are parallel to the center line SL of the bus bar 110 (Y-axis direction) and in the same direction as each other, and the FREE directions Df of the other two detection elements forming the second set (the combination of the third and fourth detection elements 143 and 144 in the example of FIG. 3) are similarly parallel to the center line SL, in the same direction as each other, and opposite to the FREE direction Df of the two detection elements forming the first set.

As some of the combinations of detection elements that satisfy these two conditions, variations 1 to 6 illustrated in FIG. 6 can be exemplified. Any of these variations can favorably limit linearity errors. However, depending on the variations that may be selected, it may not be possible to realize the first chip 130 and the second chip 140 with the same semiconductor chips using rotational symmetry as described with reference to FIG. 5. In such a case, the first chip 130 and the second chip 140 may be realized as different semiconductor chips.

In the embodiment described above, the hard bias layer provided in each detection element has been described as an example of the application portion that applies a bias magnetic field to the free layer, but the configuration of the application portion is not limited to this. Depending on the configuration of the variation, the application portion may also be a laminate including a ferromagnetic portion and an antiferromagnetic portion, which is in contact with the ferromagnetic portion and exchange-coupled with the ferromagnetic portion, (hereinafter referred to as a laminate), or an application coil. In principle, the magnetization direction of the laminate will not be reversed by a strong external magnetic field. With the application coil, the bias magnetic field can be controlled by controlling the amount of current. Moreover, the application coil is characterized by a higher freedom in element dimensions as compared with a configuration in which the application portion is a hard bias layer or a laminate. Which application portion is to be used may be determined according to the specifications required for the current sensor 100.

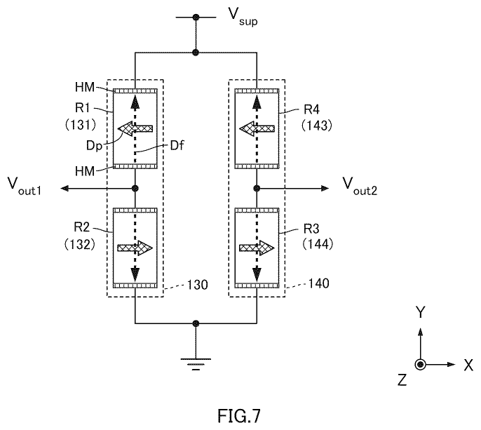

Other examples of the present embodiment are now described. In the present embodiment described above, the first detection element 131 and the second detection element 132, which are included in the first chip 130 disposed over the first bent portion 115, are incorporated into the bridge circuit as the fourth resistor R4 and the first resistor R1, respectively, and the third detection element 143 and the fourth detection element 144, which are included in the second chip 140 disposed over the second bent portion 116, are incorporated into the bridge circuit as the third resistor R3 and the second resistor R2, respectively. However, the relationship between the configuration of the bridge circuit and two semiconductor chips is not limited to this. FIG. 7 is a diagram showing another relationship between the configuration of a bridge circuit and two semiconductor chips. In the example illustrated in FIG. 7, the first detection element 131 and the second detection element 132, which are included in the first chip 130 disposed over the first bent portion 115, are incorporated into the bridge circuit as the first resistor R1 and the second resistor R2, respectively, and the third detection element 143 and the fourth detection element 144, which are included in the second chip 140 disposed over the second bent portion 116, are incorporated into the bridge circuit as the fourth resistor R4 and the third resistor R3, respectively.

The first resistor R1 (first detection element 131) and the second resistor R2 (second detection element 132) are connected in series with each other between a DC power supply and ground to form a half-bridge circuit (first half-bridge circuit), and output a first output voltage Vout, which corresponds to the strength of the magnetism applied to each of the first resistor R1 and the second resistor R2, at the midpoint between the first and second resistors R1 and R2. The fourth resistor R4 (third detection element 143) and the third resistor R3 (fourth detection element 144) are similarly connected in series with each other between the DC power supply and ground to form a half-bridge circuit (second half-bridge circuit), and output a second output voltage Vₒᵤₜ₂, which corresponds to the strength of the magnetism applied to each of the fourth resistor R4 and the third resistor R3, at the midpoint between the fourth resistor R4 and the third resistor R3. The DC power supply supplies a constant supply voltage V_{SUP}, and the first to fourth resistors R1 to R4 form a full-bridge circuit as a whole.

When the first chip 130 is disposed so as to overlap the first bent portion 115, the PIN direction Dp of the first resistor R1 agrees with the negative X-axis direction perpendicular to the center line SL. At this time, the FREE direction Df of the first resistor R1 agrees with the positive Y-axis direction parallel to the center line SL. When the current to be measured Sc flows through the first bent portion 115, the induced magnetic field Sf thus generated has a component in the positive X-axis direction (see FIG. 2), so that the resistance value of the first resistor R1 increases in accordance with the strength of the induced magnetic field Sf. When the first chip 130 is disposed so as to overlap the first bent portion 115, the PIN direction Dp of the second resistor R2 agrees with the positive X-axis direction perpendicular to the center line SL. At this time, the FREE direction Df of the second resistor R2 agrees with the negative Y-axis direction parallel to the center line SL. When the current to be measured Sc flows through the first bent portion 115, the induced magnetic field Sf thus generated has a component in the positive X-axis direction (see FIG. 2), so that the resistance value of the second resistor R2 decreases in accordance with the strength of the induced magnetic field Sf. The first output voltage Vₒᵤₜ₁ is an output obtained by dividing the supply voltage V_{SUP} by the resistance value of the first resistor R1 and the resistance value of the second resistor R2, which change as described above.

When the second chip 140 is disposed so as to overlap the second bent portion 116, the PIN direction Dp of the fourth resistor R4 agrees with the negative X-axis direction perpendicular to the center line SL. At this time, the FREE direction Df of the fourth resistor R4 agrees with the positive Y-axis direction parallel to the center line SL. When the current to be measured Sc flows through the second bent portion 116, the induced magnetic field Sf thus generated has a component in the negative X-axis direction (see FIG. 2), so that the resistance value of the fourth resistor R4 decreases in accordance with the strength of the induced magnetic field Sf. When the second chip 140 is disposed so as to overlap the second bent portion 116, the PIN direction Dp of the third resistor R3 agrees with the positive X-axis direction perpendicular to the center line SL. At this time, the FREE direction Df of the third resistor R3 agrees with the negative Y-axis direction parallel to the center line SL. When the current to be measured Sc flows through the second bent portion 116, the induced magnetic field Sf thus generated has a component in the negative X-axis direction (see FIG. 2), so that the resistance value of the third resistor R3 increases in accordance with the strength of the induced magnetic field Sf. The second output voltage Vₒᵤₜ₂ is an output obtained by dividing the supply voltage V_{SUP} by the resistance value of the fourth resistor R4 and the resistance value of the third resistor R3, which change as described above.

Accordingly, when a larger current to be measured Sc flows through the first bent portion 115 and the second bent portion 116, the first output voltage Vₒᵤₜ₁ becomes smaller and the second output voltage Vₒᵤₜ₂ becomes larger. In other words, since the first output voltage Vₒᵤₜ₁ and the second output voltage Vₒᵤₜ₂ vary complementarily depending on the magnitude of the current to be measured Sc, the full-bridge circuit as a whole is suitable as a measurement circuit for accurately measuring the magnitude of the current to be measured Sc. This configuration favorably limits linearity errors in a similar manner as described with reference to FIGS. 4A and 4B.

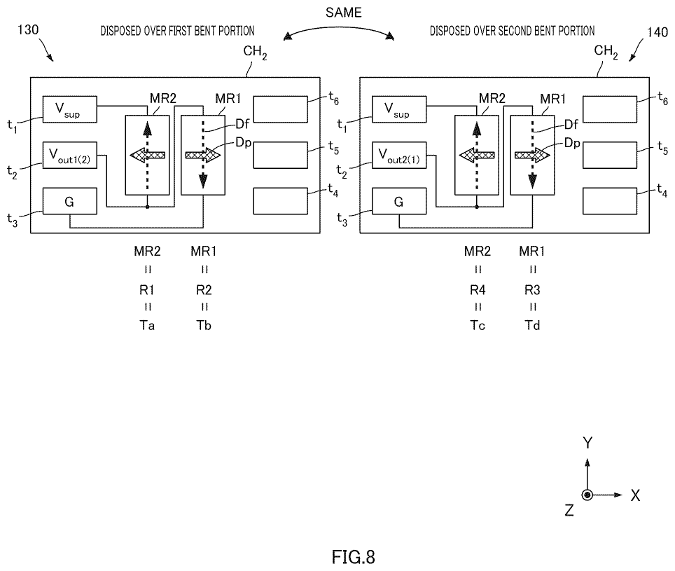

Even when the first chip 130 and the second chip 140 are configured in this manner, semiconductor chips of the same structure can be used. FIG. 8 is a diagram for illustrating another interrelationship between the two semiconductor chips (the first chip 130 and the second chip 140). In particular, the first chip 130 disposed over the first bent portion 115 is illustrated on the left side, and the second chip 140 disposed over the second bent portion 116 is illustrated on the right side.

As illustrated in the figure, semiconductor chips CH₂ with the same structure may be used as the first chip 130 and the second chip 140. The semiconductor chip CH₂ includes a detection element MR1, which is a magnetoresistive effect element located on the right side in the central portion, and a similar detection element MR2 located on the left side in the central portion, and also includes terminals t₁ to t₆, which are wired or not wired to these detection elements as illustrated in the figure. When the semiconductor chip CH₂ is placed over the first bent portion 115, it functions as the first chip 130, with the detection element MR2 located on the left side corresponding to the first arrangement Ta and the detection element MR1 located on the right side corresponding to the second arrangement Tb (see FIG. 2). The terminal t₁ functions as a power supply terminal for supplying the supply voltage V_{SUP}, the terminal t₂ functions as an output terminal for outputting the first output voltage Vout, and the terminal t₃ functions as a ground terminal.

The detection element MR1 has a fixed layer whose PIN direction Dp agrees with the positive X-axis direction when disposed over the first bent portion 115, and also a free layer whose FREE direction Df agrees with the negative Y-axis direction when a bias magnetic field is applied. The detection element MR1 having such a fixed layer and a free layer corresponds to the second resistor R2 in the full-bridge circuit (see FIG. 7). Also, the detection element MR2 includes a fixed layer whose PIN direction Dp agrees with the negative X-axis direction when disposed over the first bent portion 115, and also a free layer whose FREE direction Df agrees with the positive Y-axis direction when a bias magnetic field is applied. The detection element MR2 having such a fixed layer and a free layer corresponds to the first resistor R1 in the full-bridge circuit (see FIG. 7).

When the semiconductor chip CH₂ is placed over the second bent portion 116, it functions as the second chip 140, with the detection element MR2 located on the left side corresponding to the third arrangement Tc and the detection element MR1 located on the right side corresponding to the fourth arrangement Td (see FIG. 2). The terminal t₁ functions as a power supply terminal for supplying the supply voltage V_{SUP}, the terminal t₂ functions as an output terminal for outputting the second output voltage Vₒᵤₜ₂, and the terminal t₃ functions as a ground terminal.

The detection element MR1 has a fixed layer whose PIN direction Dp agrees with the positive X-axis direction when disposed over the second bent portion 116, and also a free layer whose FREE direction Df agrees with the negative Y-axis direction when a bias magnetic field is applied. The detection element MR1 having such a fixed layer and a free layer corresponds to the third resistor R3 in the full-bridge circuit (see FIG. 7). Also, the detection element MR2 includes a fixed layer whose PIN direction Dp agrees with the negative X-axis direction when disposed over the second bent portion 116, and also a free layer whose FREE direction Df agrees with the positive Y-axis direction when a bias magnetic field is applied. The detection element MR2 having such a fixed layer and a free layer corresponds to the fourth resistor R4 in the full-bridge circuit (see FIG. 7). In this manner, semiconductor chips CH₂ having the same structure can be used as the first chip 130 disposed over the first bent portion 115 and the second chip 140 disposed over the second bent portion 116. This contributes to reducing the number of parts and manufacturing costs.

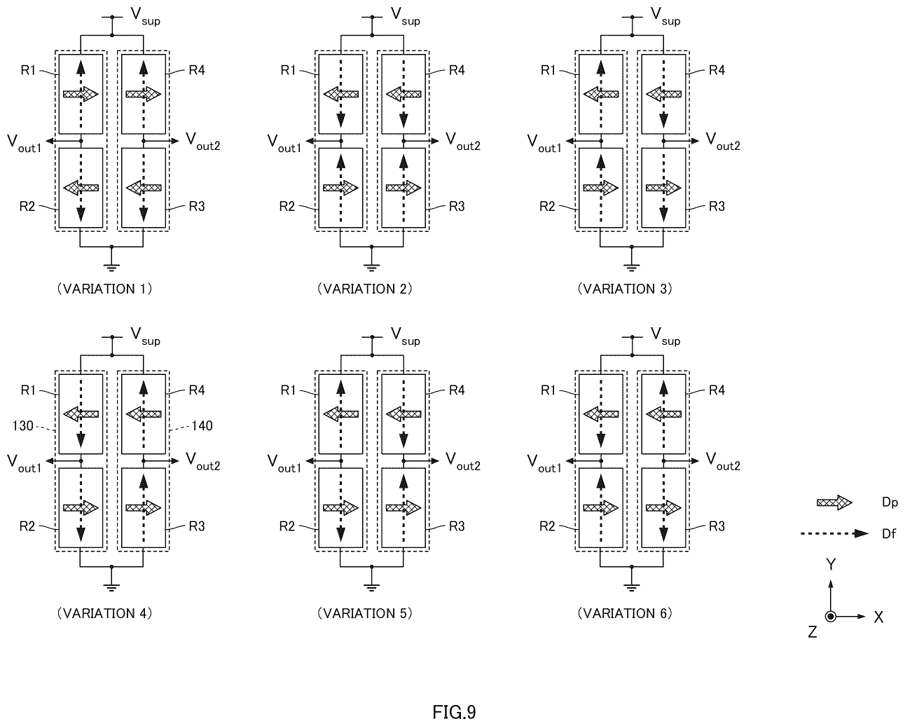

Even when the first chip 130 and the second chip 140 are configured in this manner, there are various variations of the combination of the four detection elements that can favorably limit linearity errors as illustrated in FIGS. 4A and 4B. FIG. 9 is a diagram for illustrating variations of the combination of detection elements.

The conditions for configuring the first chip 130 and the second chip 140 as illustrated in FIG. 7 include (1) the PIN directions Dp of the first detection element 131 (first resistor R1) and the second detection element 132 (second resistor R2) included in the first chip 130 are directions (X-axis directions) perpendicular to the center line SL of the bus bar 110 and opposite to each other, and the PIN directions Dp of the third detection element 143 (fourth resistor R4) and the fourth detection element 144 (third resistor R3) included in the second chip 140 are directions (X-axis directions) perpendicular to the center line SL of the bus bar 110 and opposite to each other, and (2) in a state in which the bus bar 110 is not energized and a bias magnetic field is applied, the FREE directions Df of the two detection elements forming the first set (the combination of the first and third detection elements 131 and 143 in the example of FIG. 7) among the first to fourth detection elements 131 to 144 are parallel to the center line SL of the bus bar 110 (Y-axis direction) and in the same direction as each other, and the FREE directions Df of the other two detection elements forming the second set (the combination of the second and fourth detection elements 132 and 144 in the example of FIG. 7) are similarly parallel to the center line SL, in the same direction as each other, and opposite to the FREE direction Df of the two detection elements forming the first set.

As some of the combinations of detection elements that satisfy these two conditions, variations 1 to 6 illustrated in FIG. 9 can be exemplified. Any of these variations can favorably limit linearity errors. However, depending on the variations that may be selected, it may not be possible to realize the first chip 130 and the second chip 140 in the same semiconductor chip as described with reference to FIG. 8. In such a case, the first chip 130 and the second chip 140 may be realized as different semiconductor chips. Also, as with the example illustrated in FIG. 6, the application portion may be a laminate or an application coil depending on the configuration of the variations and the specifications required for the current sensor 100.

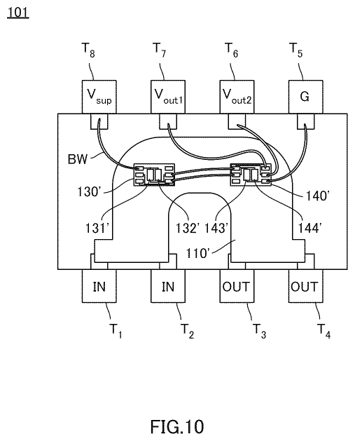

In the present embodiment described above, the current sensor 100 is constructed through a process of assembling multiple elements as illustrated in FIG. 1. However, it is also possible to form a semiconductor-type current sensor by miniaturizing each of the elements described above and accommodating them in a single semiconductor package. FIG. 10 is a diagram showing the configuration of a semiconductor-type current sensor 101. Specifically, FIG. 10 illustrates an example in which a current sensor is incorporated in a dual in-line package (DIP).

The semiconductor-type current sensor 101 has four terminals on each side (terminals T₁ to T₈). Of the terminals T₁ to T₄ arranged on one side, at least one of T₁ and T₂ is connected to one end of a current passage to be detected, and at least one of T₃ and T₄ is connected to the other end of the current passage. The bus bar 110′ is embedded in a semiconductor package, with one open end connected to the terminals T₁ and T₂ and the other open end connected to the terminals T₃ and T₄. As with the bus bar 110, the bus bar 110′ includes straight portions and bent portions. As with the first and second chips 130 and 140, the first chip 130′ and the second chip 140′ are disposed over the respective bent portions of the bus bar. The first chip 130′ includes a first detection element 131′ and a second detection element 132′, and the second chip 140′ includes a third detection element 143′ and a fourth detection element 144′. These configurations are similar to those of the first and second chips 130 and 140.

The terminal T₈ functions as a power supply terminal for supplying the supply voltage V_{SUP}, the terminal T₇ functions as an output terminal for outputting the first output voltage Vout, the terminal T₆ functions as an output terminal for outputting the second output voltage Vₒᵤₜ₂, and the terminal T₅ functions as a ground terminal. Each terminal is connected to a corresponding terminal of the first chip 130′ or the second chip 140′ by, for example, a bonding wire BW. The elements forming the current sensor are sealed with resin.

In this embodiment, each current sensor is configured as one full-bridge circuit. However, in order to detect the current value of the detection target more accurately, two or more full-bridge circuits may be configured by increasing the number of detection elements.

The present disclosure provides a current sensor or the like having good linearity of output values with respect to input values.

1. A current sensor comprising:
a bus bar including a first straight portion and a second straight portion that are on opposite sides across a center line therebetween and parallel to each other, and including a first bent portion and a second bent portion that are continuous with one end of the first straight portion and one end of the second straight portion, respectively, and are symmetrical to each other with respect to the center line;
a first detection element, a second detection element, a third detection element, and a fourth detection element, each of which is a magnetoresistive effect element including a fixed layer and a free layer, the first detection element and the second detection element being disposed over the first bent portion, and the third detection element and the fourth detection element being disposed over the second bent portion; and
an application portion configured to apply a bias magnetic field to the free layer of each of the first to fourth detection elements, wherein
when the first to fourth detection elements form a bridge circuit,
magnetization directions of the fixed layers of the first detection element and the second detection element are directions perpendicular to the center line and opposite to each other, and magnetization directions of the fixed layers of the third detection element and the fourth detection element are directions perpendicular to the center line and opposite to each other, and
in a state in which the bus bar is not energized and the bias magnetic field is applied by the application portion, magnetization directions of the free layers of two detection elements forming a first set among the first to fourth detection elements are parallel to the center line and in a same direction as each other, and magnetization directions of the free layers of the other two detection elements forming a second set are parallel to the center line, in a same direction as each other, and opposite to the magnetization directions of the two detection elements forming the first set.

2. The current sensor according to claim 1, wherein the first detection element and the second detection element over the first bent portion, and the third detection element and the fourth detection element over the second bent portion are disposed at positions that cause an angle formed between the center line and a direction of an induced magnetic field generated, when a current is applied to the bus bar, to be less than 90°.

3. The current sensor according to claim 1, wherein the first to fourth detection elements are formed on a single substrate.

4. The current sensor according to claim 1, wherein the application portion is constituted of a hard bias layer formed in each of the first to fourth detection elements.

5. The current sensor according to claim 1, wherein the application portion is constituted of a laminate including a ferromagnetic portion and an antiferromagnetic portion in contact with the ferromagnetic portion and exchange-coupled with the ferromagnetic portion.

6. The current sensor according to claim 1, wherein the application portion is constituted of an application coil.

7. The current sensor according to claim 1, wherein a first half-bridge circuit formed of the first detection element and the third detection element and a second half-bridge circuit formed of the second detection element and the fourth detection element form a full-bridge circuit as a whole.

8. The current sensor according to claim 7, wherein the first detection element and the fourth detection element are both formed on a first chip, the second detection element and the third detection element are both formed on a second chip, and the first chip and the second chip have a same structure.

9. The current sensor according to claim 7, wherein the two detection elements forming the first set are separately allocated to the first half-bridge circuit and the second half-bridge circuit, and the two detection elements forming the second set are separately allocated to the first half-bridge circuit and the second half-bridge circuit.

10. The current sensor according to claim 1, wherein a first half-bridge circuit formed of the first detection element and the second detection element and a second half-bridge circuit formed of the third detection element and the fourth detection element form a full-bridge circuit as a whole.

11. The current sensor according to claim 10, wherein the first detection element and the second detection element are both formed on a first chip, the third detection element and the fourth detection element are both formed on a second chip, and the first chip and the second chip have a same structure.

12. The current sensor according to claim 10, wherein the two detection elements forming the first set are separately allocated to the first half-bridge circuit and the second half-bridge circuit, and the two detection elements forming the second set are separately allocated to the first half-bridge circuit and the second half-bridge circuit.

13. A semiconductor-type current sensor comprising the current sensor according to claim 1 accommodated in a single semiconductor package.
